(19) United States
(12) Patent Application Publication
(10) Pub. No.: US 2007/0048915 A1
(43) Pub. Date: Mar. 1, 2007

(54) Method for forming a thin film transistor

(75) Inventor: Chin-Kuo Ting, Kuei Shan Hsiang (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Quanta Display Inc.

(21) Appl. No.: 11/370,596

(22) Filed: Mar. 8, 2006

(30) Foreign Application Priority Data
Aug. 24, 2005 (TW) 94128925

(51) Int. Cl. H01L 21/84

(52) U.S. Cl. 438/166

(57) ABSTRACT

A method for forming a thin film transistor. A buffer layer is formed on a substrate. A single crystal layer is formed on the buffer layer. An amorphous layer is formed on the single crystal layer. The amorphous layer is transferred to a crystallized layer by laser annealing. A gate dielectric layer is formed on the crystallized layer. A gate electrode is formed on the gate dielectric layer, wherein the crystallized layer is a single crystal layer or a polycrystal layer.

### BACKGROUND

The invention relates to a method for forming a thin film transistor, and in particular to a method for forming a thin film transistor of a liquid crystal display device.

Liquid crystal displays (LCD) have become widely used. Typically, an LCD includes two opposite substrates with liquid crystal interposed therebetween. Both substrates are formed with electrodes to control the orientation and arrangement of liquid crystals.

Thin film transistor liquid crystal display device, TFT-LCD, include two main types. One is an amorphous silicon TFT-LCD and another is polysilicon TFT-LCD. The electron mobility of a polysilicon TFT-LCD is about 10-100 times faster than an amorphous silicon TFT-LCD. Polysilicon TFT-LCD have been developed to act as switching devices of pixels and peripheral driving circuits of thin liquid crystal displays.

The polysilicon TFT-LCD described is typically formed by low temperature poly-silicon(LTPS) process, in which amorphous silicon is transferred to polysilicon by excimer laser annealing(ELA).

Process window for transferring amorphous silicon into polysilicon by excimer laser annealing, however, is very narrow. Currently, power stability of excimer laser process is unstable. Even if the peak to peak power variation of excimer laser process can be controlled to be below 15%, power differences still occurs in localized areas on a substrate. Power differences can change the crystal size of polysilicon layer, thus the electronic property of thin film transistor is affected.

### SUMMARY

These problems and the others are generally solved or circumvented, and technical advantages are generally achieved, by preferred illustrative embodiments of the present invention, which provide a method for forming a thin film transistor.

An embodiment of the invention provides a method for forming a thin film transistor. A buffer layer is formed on a substrate. A first single-crystal layer is formed on the buffer layer. An amorphous layer is formed on the first single-crystal layer. The amorphous layer is transferred to a crystallized layer by laser annealing. A gate dielectric layer is formed on the crystallized layer. A gate electrode is formed on the gate dielectric layer, wherein the crystallized layer is a second single-crystal layer or a polycrystal layer.

Another embodiment of the invention provides a method for transferring an amorphous layer to a crystallized layer. A buffer layer is formed on the substrate. A single crystal layer is formed on the buffer layer. An amorphous layer is formed on the single crystal layer. The amorphous layer is transferred to a crystallized layer by laser annealing.

### BRIEF DESCRIPTION OF THE DRAWINGS

The invention can be more fully understood by reading the subsequent detailed description and examples with references made to the accompanying drawings, wherein:

FIGS. 1A-1H illustrates cross section of a thin film transistor of an embodiment of the invention.

### DETAILED DESCRIPTION OF THE INVENTION

The following description discloses the best-contemplated mode of carrying out the invention. This description is made for the purpose of illustrating the general principles of the invention and should not be taken in a limiting sense. The scope of the invention is best determined by reference to the appended claims.

In this specification, expressions such as “overlying the substrate”, “above the layer”, or “on the film” simply denote a relative positional relationship with respect to the surface of the base layer, regardless of the existence of intermediate layers. Accordingly, these expressions may indicate not only the direct contact of layers, but also, a non-contact state of one or more laminated layers.

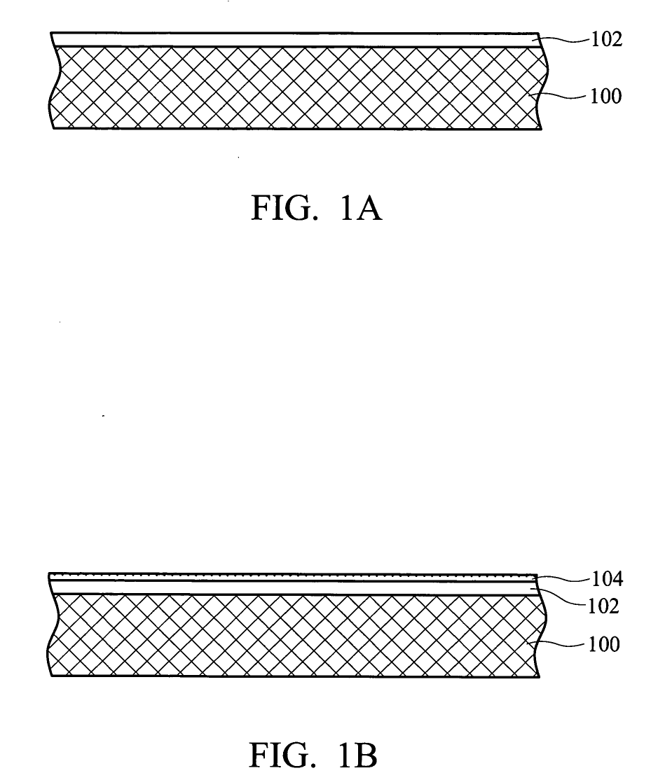

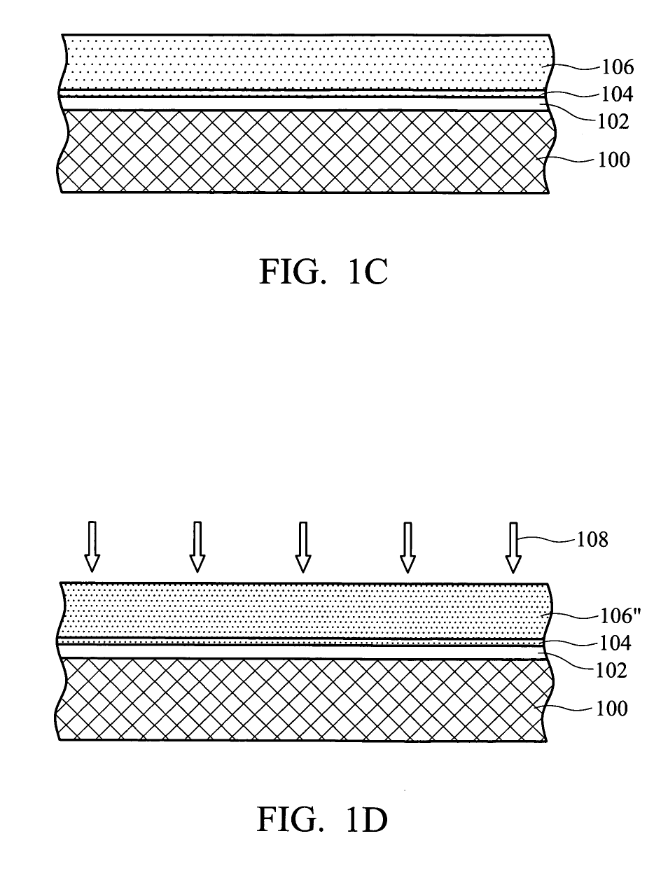

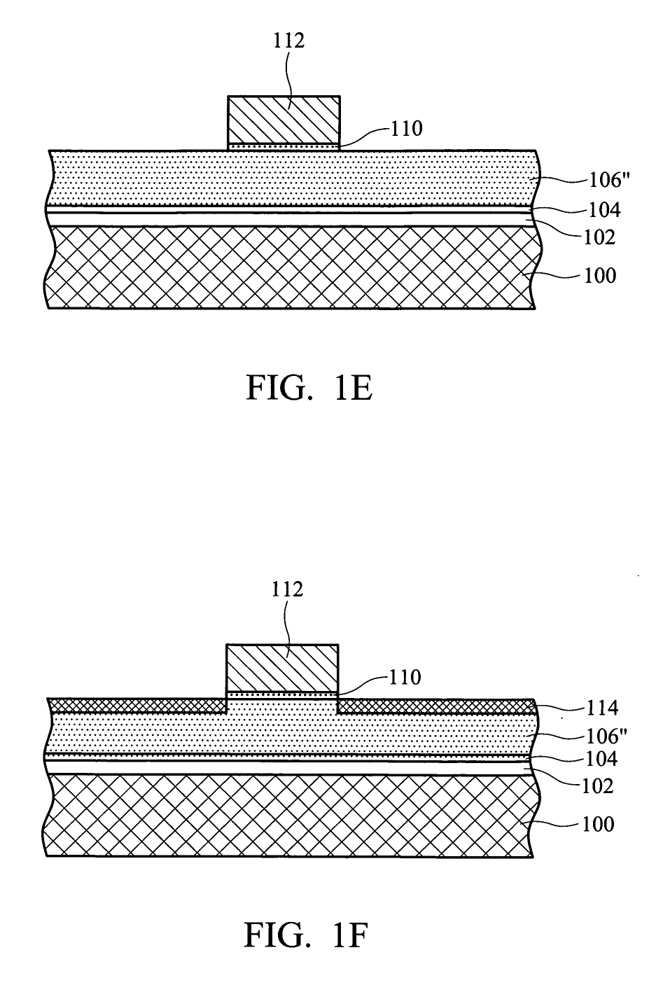

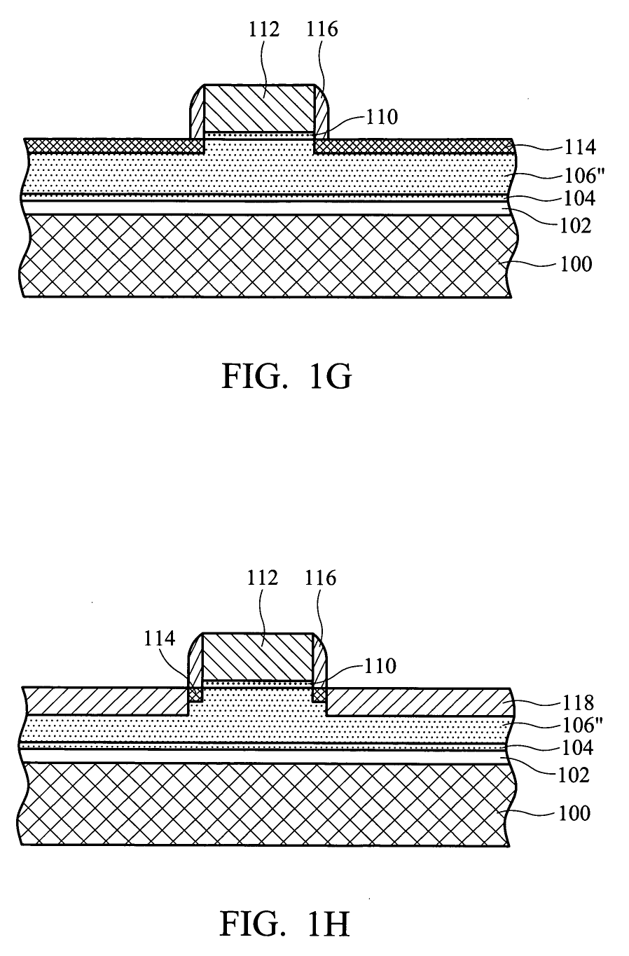

FIGS. 1A-1H illustrate cross sections of a thin film transistor of an embodiment of the invention. Referring to FIG. 1A, a substrate 100, such as a glass substrate and preferably a low-alkali or non-alkali glass substrate, is provided. Next; a buffer layer 102, such as silicon oxide layer, silicon nitride layer or silicon oxynitride layer is deposited on the substrate 100. As shown in FIG. 1B, a single crystal layer 104 is formed on the buffer layer 102. The single crystal layer 104 can be formed by molecular beam epitaxy, atomic layer epitaxy, vapor phase epitaxy or liquid phase epitaxy. Preferably, the single crystal layer 104 is a single crystal film with a thickness of about 20 Å˜200 Å.

Referring to FIG. 1C, an amorphous layer 106, preferably an amorphous silicon, is formed on the single crystal layer 104. Thickness of the amorphous layer 106 depends on product design or process window. The amorphous layer 106 can be formed by low pressure chemical vapor deposition(LPCVD), atmospheric pressure chemical vapor deposition (APCVD), plasma enhanced chemical vapor deposition (PECVD), atomic layer deposition (ALD), or the like deposition method. In a preferred embodiment of the invention, the amorphous layer 106 is formed by plasma enhanced chemical vapor deposition (PECVD).

Referring to FIG. 1D, the amorphous layer 106 is annealed by laser beam 108, such as excimer laser, to be transferred into a crystallized layer 106″, such as a polycrystal layer or a single crystal layer.

Since conventional excimer layer process cannot provide a non-melted seed layer, the process window thereof is narrow and resulting polysilicon crystal size is small. Small crystal size in the polysilicon layer occurs for two reasons. One could be that when the, Laser power is too small, the amorphous silicon at the surface is completely melted, and another portion at the bottom is only partly melted. Thus, crystal size of the polysilicon is small, and there may also be amorphous silicon interposed in polysilicon. Another reason could be that when the laser power is too high, due to fully melted amorphous silicon and lack of seed layer, uniform nucleation leads to small polysilicon crystal size. Consequently, process window of conventional technology for transferring amorphous silicon into polysilicon by excimer laser is too narrow.

In an embodiment of the invention, prior to deposition of amorphous silicon 106, a single crystal silicon film 104 is deposited to act as a seed layer. The melting point of single crystal silicon is about 1686° C., and the melting point of amorphous silicon is about 1273° C. Due to higher melting point of single crystal silicon than amorphous silicon, excimer laser power can increase at least about 15%. According to a formula of Power(E)=specific heat(S)×mass(M)×temperature×difference(ΔT), peak temperature generated by laser irradiation is about 1400° C. When laser power increases about 15%, peak temperature generated is about 1600° C. Thus, the heat caused by a temperature of less than about 1600° C. could not melt a single crystal silicon layer. The amorphous silicon 106 recrystalizes to a crystallized layer, such as a single crystal layer or a polysilicon layer, with the single crystal silicon 104 as a seed.(Consequently, the recrystalization of the amorphous silicon affected by unstable power of excimer layer could be eliminated.

Referring to FIG. 1E, a gate dielectric layer 110 and a gate electrode 112 are sequentially formed on the crystallized layer 106″. The gate dielectric layer 110 can comprise silicon oxide, silicon nitride, silicon oxynitride or other high dielectric material. The gate electrode 112 can be a single-metal layer, a dual-metal structure or a multi-layered structure selected from at least one of W, WNx, Ti, TiWx, TiNx, Ta, TaNx, Mo, Al, Cu, and the like. Any of a variety of deposition techniques, including, but not limited to, CVD, PVD, evaporation, plating, sputtering, reactive co-sputtering or combinations thereof, may allow the production of the gate electrode 112.

After formation of the gate electrode, lightly doped drain (LDD) regions, dielectric spacers, and source/drain regions are successively formed by the use of any well-known processes. For example, as shown in FIG. 1F˜FIG. 1H, a lightly doped ion implantation process is performed with various dopant species into the crystallized layer 106“to-form the LDD regions 114. The margins of the LDD regions 114 are substantially aligned, to the sidewall of the gate electrode 112. The lightly doped ion implantation process may be performed at energy between about 1 to about 100 KeV, at dosage of between about 1×10¹³ to about 1×10¹⁵ ions/cm². Advances in deposition, lithography, masking techniques and dry etching processes follow to form the dielectric spacers 116 along the sidewalls of the gate electrode 112. The dielectric spacers 116 can comprise a silicon nitride, a silicon oxide, a silicon oxynitride, or combinations thereof. A heavily doped ion implantation process is then performed and the dielectric spacers 116 are used as the mask to implant various dopant species into the crystallized Layer 106″ to form a source/drain region 118. The heavily doped ion implantation process may be performed at energy between about 1 to 100 K.V, at dosage between about 5×10¹³ to 1×10¹⁶ ions/cm2.

Consequently, in a preferred embodiment of the invention, the process window of the excimer laser annealing for transferring a amorphous silicon to a polysilicon or a single crystal silicon can increase more than about 15%. In addition, due to the use of a seed layer of a single crystal silicon, electron mobility of a thin film transistor processed with excimer laser annealing could be increased, and the problem of the insufficient electron mobility of low temperature polysilicon thin film transistors of a large size liquid crystal display panel could be solved. Further, duration of deposition of a single crystal layer with molecular beam epitaxy could be reduced.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a thin film transistor, comprising:
providing a substrate;
forming a buffer layer on the substrate;
forming a first single-crystal layer on the buffer layer;
forming a amorphous layer on the first single-crystal layer;
transferring the amorphous layer to a crystallized layer by laser annealing;
forming a gate dielectric layer on the crystallized layer;and forming a gate electrode on the gate dielectric layer,
wherein the crystallized layer is a second single-crystal layer or a polycrystal layer.

2. The method for forming a thin film transistor as claimed in claim 1, further comprises:
implanting the substrate to form a lightly doped region using the gate electrode as a mask;
forming a spacer on sidewall of the gate electrode and the gate dielectric layer; and
implanting the substrate to form a source/drain region using the gate electrode and the spacer as a mask.

3. The method for forming a thin film transistor as claimed in claim 1, wherein the laser annealing comprises excimer laser annealing.

4. The method for forming a thin film transistor as claimed in claim 1, wherein the first single-crystal layer is single crystal silicon, the amorphous layer is amorphous silicon, the polycrystal layer is polysilicon, and the second single-crystal layer is single crystal silicon.

5. The method for forming a thin film transistor as claimed in claim 3, wherein the excimer laser annealing comprises irradiating the amorphous layer using a excimer laser, wherein a temperature of about 1400° C.˜1600° C. is generated on the amorphous layer surface.

6. The method for forming a thin film transistor as claimed in claim 5, wherein the amorphous layer is in a melted state, and the first single-crystal layer is in a non-melted state.

7. The method for forming a thin film transistor as claimed in claim 1, wherein thickness of the first single-crystal layer is about 20 Å˜200 Å.

8. The method for forming a thin film transistor as claimed in claim 1, wherein the first single-crystal layer is formed by molecular beam epitaxy, atomic layer epitaxy, vapor phase epitaxy or liquid phase epitaxy.

9. The method for forming a thin film transistor as claimed in claim 1, wherein the substrate is a glass substrate.

10. A method for transferring an amorphous layer to a crystallized layer, comprising:
providing a substrate;
forming a buffer layer on the substrate;
forming a single crystal layer on the buffer layer;
forming an amorphous layer on the single crystal layer; and
transferring the amorphous layer to a crystallized layer by laser annealing.

11. The method for transferring an amorphous layer to a crystallized layer as claimed in claim 10, wherein the laser annealing comprises excimer laser annealing.

12. The method for transferring an amorphous layer to a crystallized layer as claimed in claim 10, wherein the single crystal layer is single crystal silicon, the amorphous layer is amorphous silicon, and the poly silicon layer is polycrystal silicon, and the single crystal layer is single crystal silicon.

13. The method for transferring an amorphous layer to a crystallized layer as claimed in claim 11, wherein the excimer laser annealing comprises irradiating the amorphous layer using an excimer laser, wherein a temperature of about 1400° C.˜1600° C. is generated on the amorphous layer surface.

14. A method for transferring an amorphous layer to a crystallized layer as claimed in claim 13, wherein the amorphous layer is in a melted state, and the single crystal layer is in a non-melted state.

15. The method for transferring an amorphous layer to a crystallized layer as claimed in claim 10, wherein thickness of the single crystal layer is about 20 Å˜200 Å.

16. A method for transferring an amorphous layer to a crystallized layer as claimed in claim 10, wherein the single crystal layer is formed by molecular beam epitaxy, atomic layer epitaxy, vapor phase epitaxy or liquid phase epitaxy.

17. The method for transferring an amorphous layer to a crystallized layer as claimed in claim 10, wherein the substrate is a glass substrate.
